(19) United States
(12) Patent Application Publication
(10) Pub. No.: US 2026/0090137 A1
(43) Pub. Date: Mar. 26, 2026

(54) PHOTODETECTOR COMPRISING COUPLED FABRY-PEROT RESONATORS

(71) Applicant: OFFICE NATIONAL D'ETUDES ET DE RECHERCHES AÉROSPATIALES, Palaiseau (FR)

(72) Inventors: Audrey CHU, Palaiseau (FR); Baptiste FIX, Palaiseau (FR); Emmanuel LHUILLIER, Palaiseau (FR); Julien JAECK, Palaiseau (FR); Grégory VINCENT, Palaiseau (FR); Claire ABADIE, Palaiseau (FR)

(73) Assignee: OFFICE NATIONAL D'ETUDES ET DE RECHERCHES AÉROSPATIALES, Palaiseau (FR)

(21) Appl. No.: 19/109,452

(22) PCT Filed: Jul. 24, 2023
(86) PCT No.: PCT/FR2023/051154

§ 371 Date: Mar. 6, 2025

(30) Foreign Application Priority Data
Sep. 9, 2022 (FR) FR2209042

(51) Int. Cl. H10F 77/40; H10F 39/00; H10F 39/95; H10F 77/14; H10F 77/20

(52) U.S. Cl. CPC H10F 77/413; H10F 39/018; H10F 39/806; H10F 39/809; H10F 39/95; H10F 77/14; H10F 77/206

(57) ABSTRACT

A photodetector incorporates Fabry-Perot resonators that are coupled in order to concentrate radiation to be detected in a photoconductive material. It is then possible to use photoconductive nanocrystals that are deposited from a colloidal solution of the nanocrystals, while at the same time having a high photodetection sensitivity. It is thereby possible to form a matrix-array of such photodetectors on an image sensor readout circuit, while avoiding having to join a separate detection circuit to the readout circuit using intermediate solder balls. Additionally, each photodetector may be produced easily using deposition and selective removal processes, and may be able to be reconfigured so as to have variable detection sensitivity spectra.

### TECHNICAL FIELD

The present description relates to a photodetector as well as an image sensor which comprises such photodetectors.

### PRIOR ART

Infrared light detectors are usually based on semiconductors as light-absorbing materials. These semiconductors are manufactured by epitaxy. This growth method generates a high manufacturing cost, which is due to the use of an ultra-high vacuum growth environment and also due to the mesh parameter tuning constraint between the substrate and the semiconductor.

Furthermore, the cost of infrared imagers is also due to the coupling step between the detection circuit, which includes the light-absorbing layer, and the readout circuit, which is generally implemented using CMOS technology. This coupling between the two circuits is done by indium beads. Each of these beads connects the active layer to a pixel in the CMOS readout circuit. The efficiency of this step is limited, which generates additional costs. Furthermore, the smaller the pixel size, the more complex the procedure. Small pixel sizes are desirable to improve image quality, but current dimensions (10-15 μm) are limited by this coupling step between the two circuits.

It is therefore desirable to use alternative materials to reduce the cost of infrared components. In the spectral range targeted by this invention, that is, for wavelengths above 1 um, conductive polymers are not a feasible alternative, due to the strong coupling between the exciton and the vibrations of the molecules. Other possible alternatives include semiconductor nanocrystals with low band gaps, such as lead sulfide (PbS) or mercury telluride (HgTe), or two-dimensional materials like graphene.

In materials such as nanocrystals, a compromise is necessary. The granular nature of nanoparticles means that transport takes place via nearest-neighbor hops. This transport mechanism is associated with charge carrier mobility values that are lower than in solid materials. The result is a short carrier diffusion length, typically 50 nm to 100 nm. This diffusion length is shorter than the absorption length of the electromagnetic field, which is several micrometers. Transport is therefore only effective on small sizes, but a thick film is needed to absorb most of the incident light. One strategy for overcoming this limitation is to introduce a light resonator into the light detector, whose role is to concentrate incident light on a thin layer of semiconductor whose thickness is optimal for charge collection.

Several strategies (metal-insulator-metal cavity, Fabry-Perot resonance, plasmonic resonator, etc.) have been proposed to enhance light-matter coupling in nanoparticle films, and thus enhance the absorption of the component. In the paper “Near Unity Absorption in Nanocrystal Based Short Wave Infrared Photodetectors Using Guided Mode Resonators” by Audrey Chu et al, ACS Photonics 6, 2553 (2019), the authors propose to introduce a mirror into the component to allow a double passage of incident light through the absorbing layer. This increases absorption by a factor of almost two. In addition, the authors add a grating to generate an optical mode in which light propagates along the substrate, which also generates multiple light passages through the film.

This type of strategy, based on a periodic network, suffers from two limitations. The resulting detector has a strong angular dependence, which is not favorable for integration in an imager. In addition, for optimal operation, the network must be quasi-infinite, which means that a large number of grating periods must be included in each pixel. This last point is incompatible with the aforementioned objective of reducing pixel size. It is therefore of interest to develop new light resonator geometries that are compatible with the pixel sizes used in imagers, and which also have a reduced angular dependence of their response.

It is also known to form radiation-absorbing nanostructures each consisting of a pair of coupled Fabry-Perot resonators. Each pair of coupled resonators exhibits, in addition to the respective individual resonances of each resonator, a coupling resonance that produces a value close to unity for the absorption coefficient of an incident radiation. In such coupled Fabry-Perot resonator nanostructures, the two resonators of each pair can each be formed by a trench in the surface of a metal substrate, as described in the article titled “Cooperative optical trapping in asymmetric plasmon nanocavity arrays” by Ling Guo et al., Optics Express 31324, Vol. 23, No. 24, November 2015, or in the article titled “High-quality-factor double Fabry-Perot plasmonic nanoresonator” by B. Fix et al., Optics Letters, Vol. 42, No. 24, Dec. 15, 2017, p. 5062-5065. In these structures, the standing wave components that form inside the trenches propagate perpendicular to the substrate surface. For this reason, the corresponding Fabry-Perot resonators are said to have a vertical axis. But it is also known, notably from WO 2020/002330, to form other nanostructures of coupled Fabry-Perot resonators for which the standing wave components inside the resonators propagate parallel to the substrate surface. As a result, such other Fabry-Perot resonators are said to have a horizontal axis.

Another important aspect of the invention is to generate a component whose spectral response is reconfigurable. In general, the response of an infrared detector is determined by the nature of its active layer. In the case of nanoparticles, the size of the individual building blocks determines the cutoff wavelength. Changing the cutoff wavelength therefore requires changing the active material. An alternative strategy is to have the spectral response also impacted by the presence of the light resonator. Audrey Chu et al., in ACS Photonics 6, 2553 (2019), have demonstrated that the spectral response of the material can be adjusted by the grating period while retaining the same active material. An additional degree of reconfigurability would be to be able to change the spectral response after the component has been manufactured. This type of active component is currently based on phase-change materials, or MEMS technology. Recently Dang et al, in the Nano Letters 21, 6671 (2021) article entitled “Bias Tunable Spectral Response of Nanocrystal Array in a Plasmonic Cavity”, demonstrated that it is possible to obtain a spectral response shift via voltage application. In this article, the effect is still weak. One of the challenges of this invention is to use this concept to obtain infrared detectors whose spectral response is largely reconfigurable after component manufacture.

### TECHNICAL PROBLEM

Based on this situation, one aim of the present invention is to propose a new photodetector structure that provides high optical absorptions, and simplifies the manufacture of each photodetector.

In particular, one aim of the invention may be that the photodetector structure is compatible with the use of a layer of photoconductive nanocrystals deposited from a colloidal solution.

An ancillary aim of the invention is to enable each photodetector to have reduced lateral dimensions (typically less than 15 μm, and preferentially less than 5 μm), to enable the realization of high-resolution image sensors.

A further ancillary aim of the invention is that each photodetector remains effective in detecting radiation whose angle of incidence varies within a wide angular sector.

Finally, yet another aim of the invention is to offer a photodetector whose spectral detection characteristics can be modified simply, and/or that the photodetector can be reconfigured based on its application or between two successive sequences of use of the photodetector.

### SUMMARY OF THE INVENTION

To achieve at least one or another of these aims, a first aspect of the invention proposes a new photodetector which comprises:
a substrate, which is reflective to electromagnetic radiation incident on the photodetector;
electrode portions, which are supported by the substrate, and which have respective surfaces facing away from the substrate, referred to as upper surfaces and located at a common level of spacing from the substrate;
portions of an electrically insulating material, which are located between the electrode portions and the substrate, so as to electrically insulate each electrode portion from the substrate; and
at least one portion of photoconductive material, which is arranged to be in electrical contact with two of the electrode portions which are adjacent.

When using this photodetector, at least two of the electrode portions and the substrate are designed to collect a photodetection current.

In the photodetector of the invention, a first and a second of the adjacent electrode portions delimit between them, parallel to the substrate, a volume into which, when the photodetector is in use, the radiation penetrates to be reflected by the substrate, forming a first Fabry-Perot resonator between this substrate and the level of the upper surfaces of the electrode portions. Similarly, the second electrode portion and a third of the electrode portions, which is located on a side of the second electrode portion opposite the first electrode portion, delimit between them, parallel to the substrate, a further volume into which, when the photodetector is in use, the radiation also penetrates to be reflected by the substrate, forming a second Fabry-Perot resonator between the substrate and the level of the upper surfaces of the electrode portions. In other words, the first and second Fabry-Perot resonators are designed to generate standing-wave components that propagate perpendicular to the substrate when the photodetector is in use. They are therefore of the vertical-axis type, following the terminology of the skilled person as described above.

The photodetector of the invention further has the following features /1/ to /3/:
/1/ a width of the first Fabry-Perot resonator, measured between the first and second electrode portions parallel to the substrate, is different from a width of the second Fabry-Perot resonator, measured between the second and third electrode portions also parallel to the substrate, so that the first and second Fabry-Perot resonators have respective individual resonance wavelength values, effective for the radiation incident on the photodetector, which are different, with respective values of an individual resonance quality factor of these first and second Fabry-Perot resonators such that, on one wavelength axis of the incident radiation, the following individual resonance intervals: [λᵣᵢ·(1−3/Qᵢ); λᵣᵢ·(1+3/Qᵢ)], have an overlap, where i is equal to 1 or 2 to designate the first or second Fabry-Perot resonator, respectively, and λᵣᵢ and Qᵢ are respectively the wavelength and quality factor values of the individual resonance of the Fabry-Perot resonator i. In other words, the two Fabry-Perot resonators have individual resonance wavelengths that are different without being too far apart. Additionally, these two resonators are distinguished by their respective cavity widths, which is particularly easy to achieve, especially using a masking method;
/2/ a sum of the widths of the first and second Fabry-Perot resonators with the width of the second electrode portion, measured parallel to the substrate between the volumes of the first and second Fabry-Perot resonators, is adapted to produce a coupling between the first and second Fabry-Perot resonators, by being less than a resonance wavelength value relative to the coupling, known as the coupling resonance wavelength, which is effective for the radiation incident on the photodetector, and which results from interference between at least three waves, including:
a first wave resulting from the reflection of incident radiation on the substrate;
a second wave emerging from the first Fabry-Perot resonator, resulting from a superposition of several wave components, at least one of which wave components has made at least one round trip within the volume of the second Fabry-Perot resonator; and
a third wave emerging from the second Fabry-Perot resonator, resulting from another superposition of several other wave components, at least one of which other wave components has made at least one round trip within the volume of the first Fabry-Perot resonator; and
/3/ the photoconductive material is absorbent for the coupling resonance wavelength, and the portion of this photoconductive material is located in or on at least one of the volumes of the first and second Fabry-Perot resonators.

Owing to the coupling resonance that the photodetector of the invention exhibits for the radiation that is detected, its optical absorption is very high. This is because the coupling resonance concentrates the radiation within at least part of the photoconductive material, significantly increasing the probability that a photon of the radiation will be absorbed. For this reason, the photoconductive material can be of a type compatible with a deposition method that uses a colloidal solution of nanocrystals of this material, in particular a spin coating method. Such a method reduces the cost of manufacturing the photodetector, firstly because the photoconductive material can be deposited on the substrate inexpensively, and secondly because the readout circuit can be used as a substrate for depositing the photoconductive material. In this way, the step of assembling the detection circuit to the readout circuit can be avoided.

Furthermore, since the photodetector structure of the invention can be limited to two Fabry-Perot resonators with dimensions that are smaller than the wavelength of the radiation to be detected, the photodetector can have lateral dimensions that are very small. As a result, an image sensor based on photodetectors according to the invention can provide very fine spatial resolution, and act as a high-resolution sensor.

Again owing to the structure of the photodetector of the invention, its detection efficiency is maintained within a wide angular sector for the direction of incidence of the radiation to be detected.

The portion of the photoconductive material can be located at least partially in or on whichever of the volumes of the first and second Fabry-Perot resonators has the greatest or smallest width, again measured parallel to the substrate. It can also be located at least partially in or on the two respective volumes of the first and second Fabry-Perot resonators.

In embodiments of the invention which may be simpler to manufacture, the portions of the electrically insulating material may be parts of a continuous layer of this insulating material which extends across the volumes of the first Fabry-Perot resonator and the second Fabry-Perot resonator, in addition to extending between the substrate and each electrode portion. This eliminates the need to etch the layer of insulating material.

Alternatively, in addition to the first, second and third electrode portions, the substrate can also be in contact with the photoconductive material portion, so as to form an additional electrode portion. In particular, the substrate may be in contact with the portion of photoconductive material because part(s) of the latter is (are) contained within the volume of at least one of the first and second Fabry-Perot resonators. In this case, at least two of the first, second and third electrode portions can be electrically short-circuited to form a first photodetection current collection electrode, and the substrate can be used to form a second photodetection current collection electrode. Alternatively, the photodetection current can be collected between any two subsets of the electrode portions, these being electrically short-circuited within each subset.

Generally speaking, the photodetector can further comprise an biasing electrical circuit which is adapted to apply, during use of the photodetector, a variable electrical voltage between two of the electrode portions which collect the photodetection current, and to optionally vary this electrical voltage between two successive uses of the photodetector. Owing to such a variable bias voltage, the detection sensitivity of the photodetector, and more generally its sensitivity spectrum, can be modified, and in particular adapted to different uses. The variable bias voltage increases the efficiency with which the electrode portions collect the electrical charges created by radiation in the photoconductive material. The bias voltage can vary between 0 V (volt) and 10 V, but values of 1 V or less may advantageously be sufficient. Advantageously, such a photodetector can be adapted so that a radiation absorption value at least at one wavelength value varies by at least 30%, preferably at least 50%, even more preferably at least 90%, between a first use of the photodetector with no electrical voltage applied by the biasing electrical circuit between the two electrode portions, or during which the voltage applied by the biasing electrical circuit is zero, and a second use of the same photodetector during which the voltage applied by the biasing electrical circuit is non-zero.

In one embodiment, the electric fields applied to operate the component are below 100 kVcm⁻¹, and preferentially below 30 kV·cm⁻¹

Again generally for the invention, the photodetector may also comprise a reconfiguration circuit which is adapted to select and electrically connect at least two of the electrode and substrate portions of the photodetector in order to collect photodetection current by those electrode and substrate portions which are selected. These can vary between several modes of photodetection current collection, which are associated with different respective spectra of photodetector sensitivity to incident radiation. Indeed, each of the modes may prefer to collect photodetection current through a part of the photoconductive material that is different from that of another mode, and each part of the photoconductive material may be the locus of concentration of the radiation to be detected for a different value of the latter's wavelength. In this way, the photodetector of the invention can be reconfigured simply and instantly between two successive uses. For example, a first of the photodetection current collection modes may use the first and second electrode portions to collect the current, and another mode may use the second and third electrode portions. Thus, the first collection mode may correspond to the coupling resonance created by the photodetector structure of the invention, while the other collection mode may correspond instead to the individual resonance of one of the Fabry-Perot resonators, this individual resonance and the coupling resonance corresponding to different wavelength values for the radiation to be detected. Possibly, for at least one or each of the collection modes, each electrode portion that is not used to collect photodetection current can be short-circuited by the reconfiguration circuit with one of the selected electrode portions. Alternatively, an electrode portion that is not used to collect photodetection current can be at a floating potential.

Advantageously, the photodetector can have at least one of the following additional features, separately or several of them in combination:
the substrate can have a flat surface which extends continuously under the portions of insulating material and under the volumes of the first and second Fabry-Perot resonators;
the substrate can comprise a readout circuit for the photodetector;
each portion of the photoconductive material can be part of a layer of this photoconductive material which extends continuously over the volumes of the first and second Fabry-Perot resonators and over the electrode portions;
the photodetector may comprise a plurality of pairs of coupled first and second Fabry-Perot resonators, with first, second and third electrode portions associated with each pair and electrically connected to accumulate photodetection currents which arise from each pair when the photodetector is in use. In the case of such a photodetector with several pairs of coupled Fabry-Perot resonators, a repetition pitch of a pattern of the pairs of coupled Fabry-Perot resonators on the substrate is smaller than the coupling resonance wavelength;
the photodetector can have lateral dimensions between 1 μm (micrometer) and 1 cm (centimeter), preferably between 1 μm and 100 μm, in particular less than 15 μm, measured parallel to the substrate;
the volumes of the first and second Fabry-Perot resonators, as well as the width of the second electrode portion, can be dimensioned so that the coupling resonance wavelength is between 1 μm and 12 μm, preferably between 1 μm and 2.5 μm;
the photoconductive material can be selected to have a band gap of less than 0.8 eV (electro-volt). This limit corresponds to photodetectors that are effective for wavelength values of the radiation to be detected that are greater than around 1 μm. In particular, the photoconductive material may be based on lead sulphide (PbS), mercury telluride (HgTe) or graphene; and
each portion of photoconductive material can be made up of agglomerated nanocrystals. Such nanocrystals can be deposited from a colloidal solution.

A second aspect of the invention proposes an image sensor which comprises a matrix arrangement of photodetectors, each photodetector conforming to the first aspect of the invention presented above.

When each of the image sensor's photodetectors comprises several pairs of coupled Fabry-Perot resonators, with electrode portions associated with each pair and electrically connected to accumulate photodetection currents that originate from each pair when the photodetector is in use, the number of pairs of coupled Fabry-Perot resonators can be less than or equal to five within each photodetector. Alternatively or in combination, each photodetector can have an individual photodetector size, measured along a direction of juxtaposition of the pairs of coupled first and second Fabry-Perot resonators, which is less than or equal to ten times a wavelength value of the radiation corresponding to a maximum detection sensitivity of the photodetector.

Finally, a third aspect of the invention proposes a method for manufacturing a photodetector according to the first aspect of the invention, according to which the portions of photoconductive material are obtained from a deposit of a colloidal solution which incorporates nanocrystals of the photoconductive material, followed by drying of the deposited colloidal solution. In particular, the photoconductive material portions can be obtained using a spin-coating method.

### BRIEF DESCRIPTION OF THE FIGURES

The features and advantages of the present invention will become clearer in the following detailed description of non-limiting embodiments, with reference to the appended figures, among which:

FIG. 1a is a cross-sectional view of a photodetector according to the invention;

FIG. 1b corresponds to FIG. 1a for an alternative embodiment of the photodetector;

FIG. 1c corresponds to FIG. 1a for another alternative embodiment of the photodetector;

FIG. 1d corresponds to FIG. 1a for yet another alternative embodiment of the photodetector;

FIG. 2 is a planar view of a photodetector according to any one of FIG. 1a-FIG. 1d;

FIG. 3a is a spectral absorption diagram for a photodetector according to FIG. 1b;

FIG. 3b is a spectral detection response diagram for a photodetector according to FIG. 1b and FIG. 2;

FIG. 4a corresponds to FIG. 2 for another mode of grouping electrode portions;

FIG. 4b corresponds to FIG. 3b for the photodetector in FIG. 4a;

FIG. 5a also corresponds to FIG. 2 for yet another mode of grouping electrode portions;

FIG. 5b corresponds to FIG. 3b for the photodetector of FIG. 5a;

FIG. 6 corresponds to FIG. 1a for an improvement of the invention; and

FIG. 7 is a perspective view of an image sensor according to the invention.

### DETAILED DESCRIPTION OF THE INVENTION

For the sake of clarity, the dimensions of the elements shown in these figures do not correspond to actual dimensions or dimension ratios. In addition, some of these elements are shown only symbolically, and identical references shown in different figures designate elements that are identical or have identical functions.

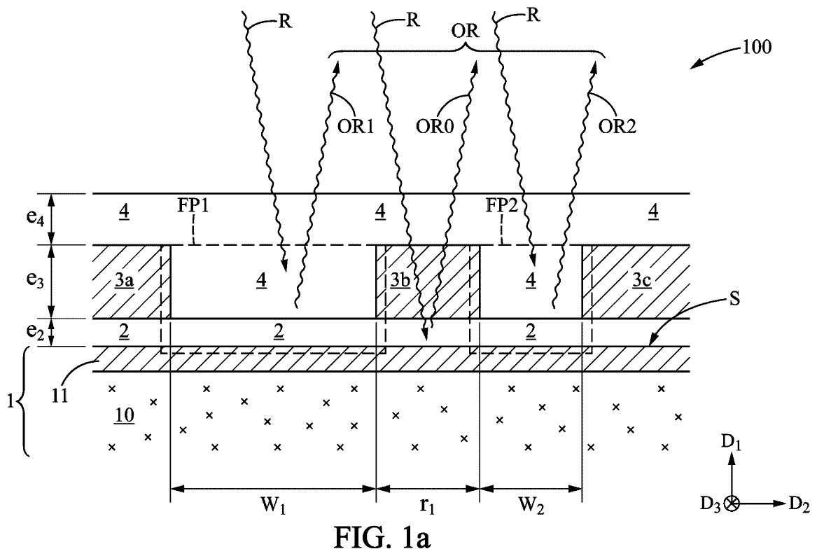

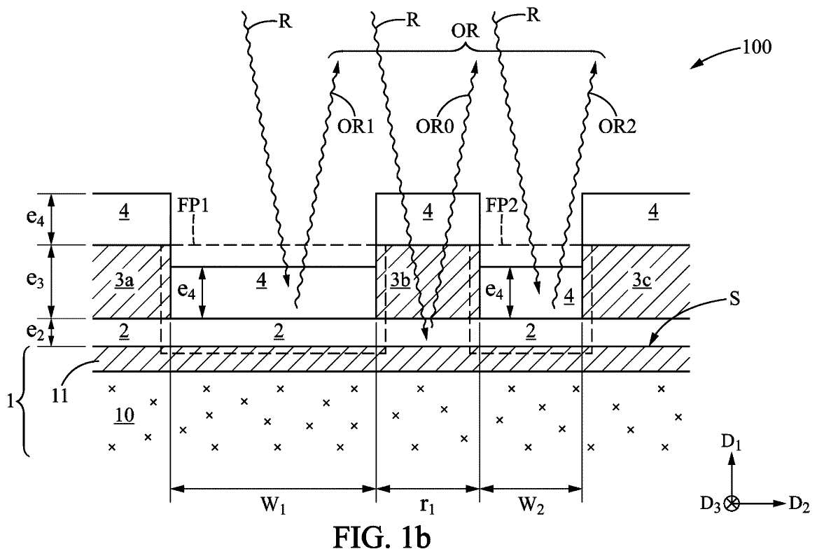

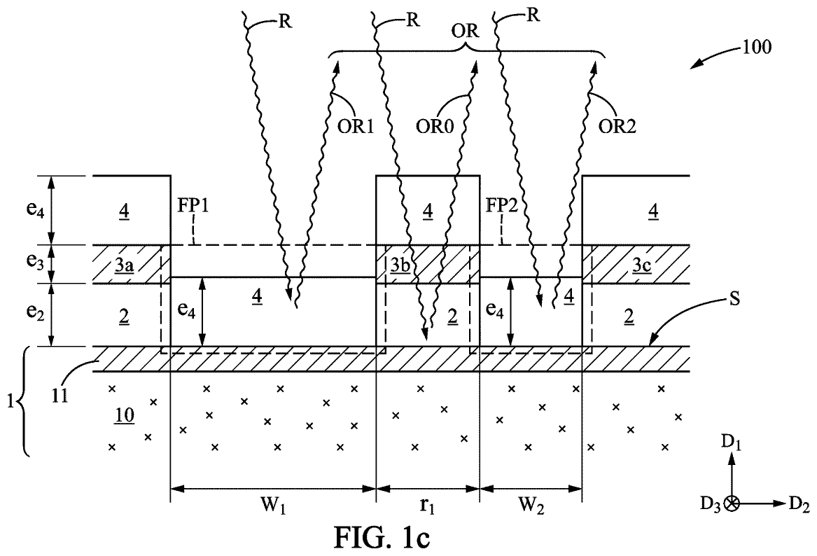

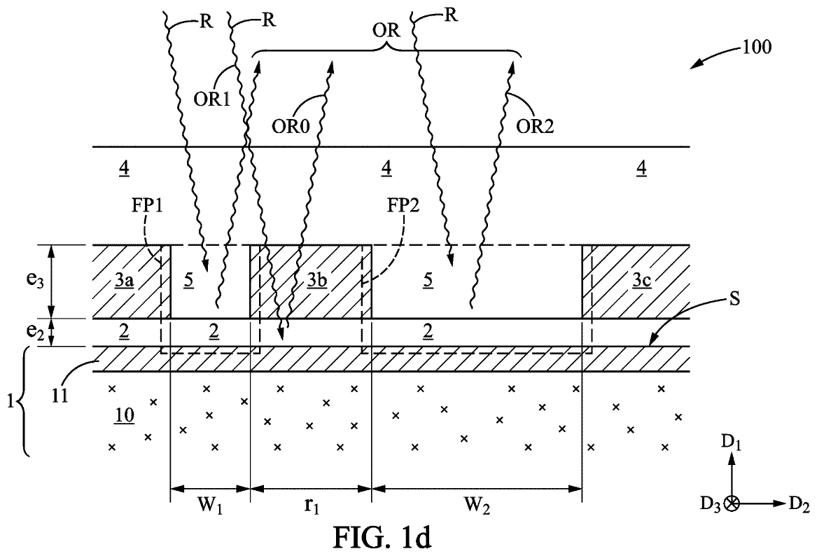

In accordance with the particular embodiment shown in FIG. 1a, a substrate 1 of the photodetector 100 has a continuous, flat, reflective upper surface S for radiation R to be detected which is incident on this surface. For this purpose, the surface S of the substrate 1 can be formed by a continuous metal layer 11, which is supported by a base portion 10 of the substrate 1. This base portion 10 can be at least partly silica, quartz, calcium fluoride (CaF₂), undoped silicon (Si), undoped germanium (Ge), zinc selenide (ZnSe), zinc sulfide (ZnS), potassium bromide (KBr), lithium fluoride (LiF), alumina (Al₂O₃), potassium chloride (KCl), barium fluoride (BaF₂), cadmium telluride (CdTe), sodium chloride (NaCl), cesium bromide (CsBr), gallium arsenide (GaAs), magnesium fluoride (MgF₂), or thallium bromo-iodide (Br₃₋ₓIₓTI), in particular. Alternatively, the base portion 10 of the substrate 1 can incorporate a readout circuit for the photodetector 100, in particular such a readout circuit implemented in CMOS technology. The metal layer 11 can be made of gold (Au), silver (Ag) or aluminum (Al), in particular, or an alloy, or it can be a superposition of several elementary metal layers.

The substrate 1 is covered by a continuous insulating layer 2, for example a layer of silica (SiO₂) or alumina (Al₂O₃), on top of the metal layer 11. In particular, the insulating layer 2 can be made of alumina and have a thickness e2 of around 50 nm (nanometer) measured parallel to the direction D₁, which is perpendicular to the surface S of the substrate 1.

The thickness of the insulating layer 2 can be between 10 nm and 10 μm, preferentially between 30 nm and 5 ρm.

Three electrode portions, designated 3a, 3b and 3c, respectively, are formed on the insulating layer 2. They can be obtained from a continuous metal layer, for example a layer of gold, silver or aluminum, which is then etched to form separating gaps between adjacent electrode portions. Alternatively, the electrode portions 3a, 3b and 3c can be deposited using a lift-off method, where a resin pattern is first formed on the insulating layer 2, followed by deposition of the electrode material and subsequent dissolution of the resin, simultaneously removing the electrode material at the locations of the resin pattern. The common thickness es of the electrode portions 3a, 3b and 3c can be around 100 nm, in the direction Di. Each electrode portion 3a, 3b, 3c is thus electrically insulated from the metal layer 11 by the insulating layer 2.

Finally, a layer 4 of a photoconductive material is deposited in the separating gaps between the electrode portions 3a, 3b and 3c, so as to be in contact with the two electrode portions on either side of each of these separating gaps. In the embodiment shown in FIG. 1a, the layer of photoconductive material 4 also continuously covers the three electrode portions 3a, 3b and 3c.

In possible embodiments of the photodetector 100, the photoconductive material of the layer 4 may be a two-dimensional material such as graphene or a transition metal chalcogenide such as molybdenum sulfide (MoS₂), molybdenum selenide (MoSe₂), molybdenum telluride (MoTe₂), tungsten sulfide (WS₂), tungsten selenide (WSe₂), tungsten telluride (WTe₂), or alloys or heterostructures thereof. Agglomerated nanocrystals of these transition metal chalcogenides can be deposited over the electrode portions 3a, 3b and 3c from colloidal solutions of these nanocrystals, using a spin coating method, so as to fill the inter-electrode separation gaps.

In other possible embodiments of the photodetector 100, the photoconductive material of the layer 4 may be a conductive polymer such as a mixture of poly(3,4-ethylenedioxythiophene) and sodium polystyrene sulfonate), designated PDOT-PSS, or such as poly(3-hexylthiophene-2,5), designated P3HT. These conductive polymers can also be deposited over the electrode portions 3a, 3b and 3c using a spin coating method, again so as to fill the inter-electrode separation gaps.

In yet other possible embodiments of the photodetector 100, the photoconductive material of the layer 4 may consist of nanocrystals of silicon (Si), germanium (Ge), cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), lead sulfide (PbS), lead selenide (PbSe), lead telluride (PbTe), copper indium sulfide (CuInS₂), copper indium selenide (CuInSe₂), silver indium sulfide (AgInS₂), silver indium selenide (AgInSe₂), copper II sulfide (CuS), copper I sulfide (CU2S), silver sulfide (Ag₂S), silver selenide (Ag₂Se), silver telluride (Ag₂Te), indium nitride (InN), indium phosphide (InP), indium arsenide (InAs), indium antimonide (InSb), indium sulfide (In₂S₃), cadmium phosphide (Cd₃P₂), zinc phosphide (Zn₃P₂), cadmium arsenide (Cd₃As₂), zinc arsenide (Zn₃As₂), zinc oxide (ZnO), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), iron sulfide (FeS₂), titanium oxide (TiO₂), bismuth sulfide (Bi₂S₃), bismuth selenide (Bi₂Se₃), bismuth tellurium (Bi₂Te₃), molybdenum sulfide (MoS₂), tungsten sulfide (WS₂), vanadium oxide (VO₂), lead cesium chloride (CsPbCl₃), lead cesium bromide (CsPbBr₃), lead cesium iodide (CsPbI₃), methyl ammonium lead iodide or MAPI (CH₃NH₃PbI₃), formamidinium lead iodide or FAPI (N₂H₄PbI₃), alloys or heterostructures thereof. Such nanocrystals can be spherical or tetrahedral in shape, or in the form of platelets, rods, wires, tripods etc. The layer 4 can then be deposited by spin-coating from a solution of the nanocrystals used. In this solution, the nanocrystals can be coated with ligands such as carboxylic acids, amines, thiols or phosphines. Alternatively, they can be coated with ionic ligands such as S²⁻ (sulfide), OH⁻ (hydroxide), HS⁻ (hydrosulfide), Se²⁻ (selenide), NH²⁻ (amide), Te²⁻ (tellurium), SCN⁻ (thiocyanate), Cl⁻ (chloride), Br⁻ (bromide), I⁻ (iodide), Cd²⁺ (cadmium), NH₄⁺ (ammonium), Hg²⁺ (mercury), Zn²⁺ (zinc) and Pb²⁺ (lead).

In another embodiment, the nanocrystals used to form a photoconductive film are coated with a mixture of organic and inorganic ligands, such as mercaptoethanol and mercurous chloride (HgCl₂) solubilized in dimethylformamide.

Typically, the layer of photoconductive material 4 may have a thickness e4 of around 80 nm, measured parallel to the direction D₁, above the electrode portions 3a, 3b and 3c in addition to filling the inter-electrode separating gaps. Depending on the photoconductive material used, its electrical carriers can have a mobility of between about 10⁻⁴ cm²·V⁻¹·s⁻¹ (square centimeters per volt per second) and about 50 cm²·V⁻¹·s⁻¹, preferably between about 10⁻³ cm²·V⁻¹·s⁻¹ and about 10 cm²·V⁻¹·S⁻¹. Its optical refractive index can be between 1 and 4, more particularly between 1.3 and 3. The layer 4 of this photoconductive material can then be absorbent between 200 nm and 15 μm, preferentially between 1 μm and 5 μm, and even more preferentially between 1 μm and 2.5 μm, with an absorption coefficient value per unit thickness of the layer 4 which is between 100 cm⁻¹ and 10,000 cm⁻¹, and more particularly between 1,000 cm⁻¹ and 5,000 cm⁻¹.

In the photodetector 100, the separating gap between the electrode portions 3a and 3b on the one hand, and that between the electrode portions 3b and 3c on the other hand, are of essential importance for photodetector operation. Each is a Fabry-Perot resonator with a vertical axis, that is, for which the propagation directions of the standing-wave components are parallel to the direction Di. In the figures, FP1 designates the Fabry-Perot resonator located between the electrode portions 3a and 3b, and FP2 designates the Fabry-Perot resonator located between the electrode portions 3b and 3c. In direction D₁, each of the Fabry-Perot resonators FP1 and FP2 is bounded on the one hand by the metal layer 11, and on the other hand by a straight extension between the upper surfaces of the electrode portions, away from the substrate 1, over the inter-electrode separating gaps. Transversely, that is, along direction D₂, each of the Fabry-Perot resonators FP1 and FP2 is bounded by the edges of the electrode portions. Thus, in the embodiment shown in FIG. 1a, the volume of each Fabry-Perot resonator FP1, FP2 includes a portion of the insulating layer 2 that lies in line with the corresponding inter-electrode separating gap, along direction D₁. It further comprises an inter-electrode gap filling portion made of the photoconductive material used for the layer 4. In this case, the phase-matching relationship for each Fabry-Perot resonator FP1, FP2, established for two propagation directions that are parallel to the direction D₁ but have opposite orientations, takes into account the superposition of the insulating layer material 2 and the photoconductive material.

Additionally, the two Fabry-Perot resonators FP1 and FP2 have different widths, measured parallel to the direction D₂. For example, the width of the resonator FP1, denoted W₁, may be 400 nm, and that of the resonator FP2, denoted W₂, may be 200 nm. However, the width of each resonator contributes to the effective value of each refractive index involved in the phase matching relationship for that resonator FP1, FP2, so that the two resonators FP1 and FP2, taken separately, have respective resonance wavelength values, known as individual resonance wavelength values, which are different. The width of the electrode portion 3b, between the two resonators FP1 and FP2, is denoted rᵢ. For the embodiment shown in FIG. 1a, rᵢ may be equal to 200 nm.

In the variant shown in FIG. 1b, the layer of photoconductive material 4 is discontinuous and has a thickness that is identical between the locations that are situated in each of the resonators FP1, FP2 and the locations that are situated above each of the electrode portions 3a, 3b and 3c. The insulating layer 2 is still continuous over the entire surface S in the photodetector 100, with a thickness e₂ that may still be equal to 50 nm. The thickness es of each electrode portion 3a, 3b, 3c can still be equal to about 100 nm, and the thickness e4 of the layer of photoconductive material 4 can be equal to about 80 nm everywhere. The portions of the layer 4 that are located in each of the resonators FP1 and FP2 are still in contact with the adjacent electrode portions: the portion of the layer 4 that is located in the resonator FP1 is in contact with the electrode portions 3a and 3b, and that which is located in the resonator FP2 is in contact with the electrode portions 3b and 3c. The numerical values for the widths W₁, W₂ and rᵢ can remain identical to those cited in connection with FIG. 1a.

The embodiment of FIG. 1c corresponds to that of FIG. 1b by removing the insulating layer 2 inside each of the resonators FP1 and FP2. Such selective removal of material from the insulating layer 2 can be carried out in any of the ways well known to those skilled in the art, so it is not necessary to describe it here. The following numerical values can be adopted: e₂=120 nm, e₃=70 nm and e₄=140 nm, while the numerical values of W₁, W₂ and rᵢ can remain the same as in the embodiments of FIG. 1a and FIG. 1b. For the thickness values just given, the portions of the layer 4 that are located in each of the resonators FP1 and FP2 are still in contact with the adjacent electrode portions. In the embodiment shown in FIG. 1c, the metal layer 11 of the substrate 1 is in contact with the portions of photoconductive material 4 located in each of the resonators FP1 and FP2. As a result, the metal layer 11 can be used as an additional electrode portion, in addition to the electrode portions 3a, 3b and 3c. The advantages of adding an additional electrode, particularly in this way, will be explained later in this description.

Finally, in the embodiment shown in FIG. 1d, the inter-electrode gaps between the electrode portions 3a and 3b in the resonator FP1, and between the electrode portions 3b and 3c in the resonator FP2, are filled with planarizing resin up to the top surface of the electrode portions 3a, 3b and 3c. The layer of photoconductive material 4 then has parallel faces, and continuously covers the electrode portions 3a, 3b and 3c as well as the resin portions 5. The insulating layer 2 can again be continuous throughout the photodetector 100. The following numerical values can be adopted for the embodiment of FIG. 1d: e₂=50 nm, e₃=130 nm, e₄=140 nm, W₁=400 nm, W₂=1050 nm, r₁=725 nm, and the layer 4 can consist of a graphene sheet.

For the embodiment shown in FIG. 1b and the associated numerical values, and when the photoconductive material of the layer 4 is mercury tellurium (HgTe), the Fabry-Perot resonator FP1 has an individual resonance wavelength value λ₁, effective for an incident radiation R in the direction of the surface S, which is equal to about 1650 nm (nanometer), with an individual resonance quality factor value Q₁ equal to about 5, and the Fabry-Perot resonator FP2 has an individual resonance wavelength value λ₂ equal to about 1550 nm, with an individual resonance quality factor value Q₂ equal to about 5. The individual resonance range [λr₁·(1−3/Q₁); λr₁·(1+3/Q₁)] of the resonator FP1 is [660 nm; 2640 nm], and that [λr₂·(1−3/Q₂); λr₂·(1+3/Q₂)] of the resonator FP2 is [620 nm; 2480 nm]. These two intervals therefore overlap between 660 nm and 2480 nm. Similar individual resonances exist for the embodiments of FIG. 1a, FIG. 1c and FIG. 1d.

Generally speaking, the electrode portion 3b, which separates the two Fabry-Perot resonators FP1 and FP2, has a width, measured along the direction D₂ and noted rᵢ, which is sufficiently small for these two resonators to be coupled. Under the conditions just described in connection with FIG. 1b, and again when the photoconductive material of the layer 4 is lead sulfide (PbS), the two Fabry-Perot resonators FP1 and FP2 exhibit a coupling resonance that has a resonance wavelength value, called the coupling resonance wavelength, of around 1.55 μm, with an associated quality factor, called the coupling resonance quality factor, of around 15. This coupling resonance is produced by interference between the following three waves, for each monochromatic component of the radiation R:
a portion of the radiation R that is reflected on the surface S of the substrate 1, that is, reflected by the metal layer 11. This part of the radiation which is reflected only once is designated by the reference ORO in the figures;
a first additional wave, OR1, which emerges from the Fabry-Perot resonator FP1, and which results from a superposition of several wave components, at least one of which has traveled back and forth inside the Fabry-Perot resonator FP2. In other words, the amplitude of the additional wave OR1 depends on the coupling between the resonator FP1 and the free space from which the radiation R originates. Additionally, at least one component of this additional wave OR1 has propagated in the resonator FP2, making at least one round trip parallel to the direction D1, then has passed through the intermediate space between the two resonators FP1 and FP2, before being retransmitted into the free space by the resonator FP1. Additional wave components, which may further participate in constituting the additional wave OR1, may have made any combination of successive round trips in the two resonators FP1 and FP2, with crossings of the intermediate space between the two resonators FP1 and FP2 at each passage between a round trip in one of the resonators FP1 or FP2 and a round trip in the other resonator, before each being retransmitted into the free space by the resonator FP1; and
a second additional wave, OR2, which emerges from the Fabry-Perot resonator FP2, and is the result of a superposition of several other wave components, at least one of which has traveled back and forth inside the Fabry-Perot resonator FP1. In other words, the amplitude of the additional wave OR2 depends on the coupling between the resonator FP2 and the free space from which the radiation R originates. Additionally, at least one component of the additional wave OR2 has propagated in the resonator FP1, making at least one round trip parallel to the direction D1, then has passed through the intermediate space between the two resonators FP1 and FP2, before being retransmitted into the free space by the resonator FP2. As in the case of the additional wave OR1, other additional wave components, which may further participate in constituting the additional wave OR2, may have made any combination of round trips in the two resonators FP1 and FP2, with crossings of the intermediate space between the two resonators FP1 and FP2 at each passage between a round trip in one of the resonators FP1 or FP2 and a round trip in the other resonator, before each being retransmitted into the free space by the resonator FP2.

The two additional waves OR1 and OR2 are due to the coupling between the two Fabry-Perot structures FP1 and FP2. Then, for a particular value of the radiation wavelength R, the reflected wave OR0, the first additional wave OR1 and the second additional wave OR2 form a constructive interference that helps to constitute a total reflected wave OR, which is the object of the coupling resonance. When the wavelength of the radiation R is equal to the wavelength value of the coupling resonance, the absorption coefficient of the photodetector 100 is substantially equal to 1, and is less than 0.2 outside the coupling resonance range. A criterion for sufficient coupling between the resonators FP1 and FP2, for the photodetectors 100 of FIG. 1a-FIG. 1d, is that the sum of the widths W₁+r₁+W₂ is less than the value of the coupling resonance wavelength, noted λ_{c}.

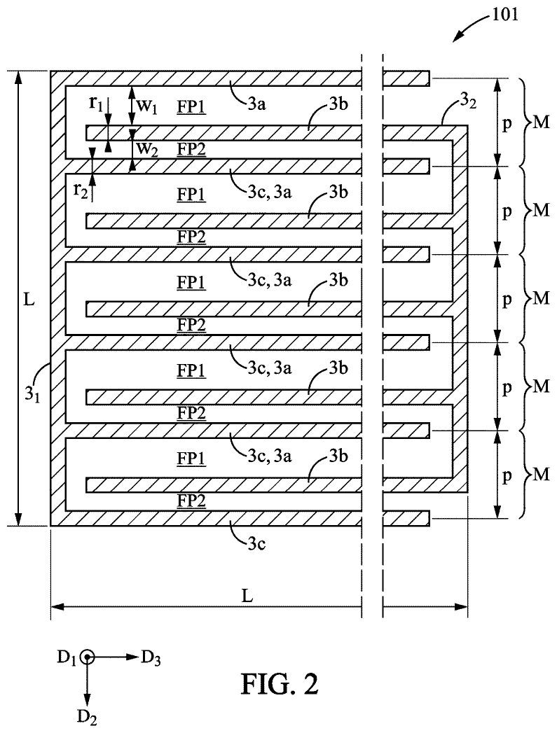

Each of the photodetectors 100 in FIG. 1a-FIG. 1d can be reproduced several times in the direction D₂, forming a repetition pattern M with a repetition pitch designated by p. A new photodetector 101 is thus obtained, consisting of several elementary photodetectors 100 arranged electrically in parallel. FIG. 2 shows such a photodetector 101, consisting of five elementary photodetectors 100 associated by their electrode portions 3a/3c. All of the electrode portions 3a/3c and 3b extend longitudinally in direction D₃. The electrode portions 3a/3c belong to the electrode 31 of the resulting photodetector 101, and the electrode portions 3b belong to its electrode 32. By way of illustration, the repetition pitch p inside the photodetector 101 may be equal to 1 μm, for example when the width r₂ of each electrode portion 3a/3c in the direction D₂ is equal to 200 nm, or when W₁=400 nm, W₂=200 nm and r₁=200 nm. In this case, the photodetector 101 can have lateral dimensions L in the directions D₂ and D₃ of the order of 6 μm. Such a photodetector 101 produces a photodetection current that is greater than that of each of the elementary photodetectors 100, substantially in a ratio equal to the number of elementary photodetectors 100 that are grouped together in the photodetector 101.

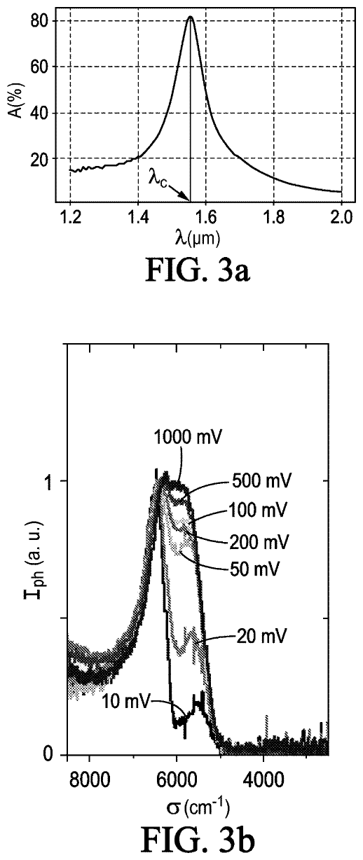

The diagram in FIG. 3a shows the spectral absorption of a photodetector 101 that consists of a very large number of repetitions of the pattern M when this pattern is the elementary photodetector 100 of FIG. 1b. The following numerical values have been adopted for this example: r₁=r₂=200 nm, W₁=400 nm, W₂=200 nm, p=1 μm, e₂=50 nm, e₃=100 nm and e₄=80 nm. The value Ac of the coupling resonance wavelength remains substantially equal to 1.5 μm, and is associated with a value Q_{c} of the coupling resonance quality factor which is equal to about 15. In the diagram of FIG. 3a, the horizontal axis marks the wavelength values for the monochromatic radiation R, noted λ and expressed in micrometers (μm), and the vertical axis marks the spectral absorption values, noted A and expressed in percent (%). Spectral absorption is greater than 80% for the value λ_{c} of the coupling resonance wavelength, and less than 20% outside the coupling resonance range [λ_{c}·(1−3/Q_{c}); λ_{c}·(1+3/Q_{c})]. Additionally, the value λ_{c} of the coupling resonance wavelength varies by less than 0.1 μm in absolute value when the incidence of the radiation R in the plane of the directions D₁ and D₂ varies by ±25° (degree) with respect to the direction D₁. At the same time, the value A(λ_{C}) of the absorption for the coupling resonance wavelength λ_{c} varies by less than 10%. Such small variations in the values of λ_{c} and A(λ_{C}) provide the photodetector 101 with a great angular tolerance in its photodetection efficiency. Finally, the coupling resonance wavelength λ_{c} varies little with the number of elementary photodetectors 100 arranged in parallel to form the photodetector 101: it varies by around 0.025 μm between five and an infinite number of elementary photodetectors 100.

In general, a photodetector that conforms to the invention may have the following additional features:
the photodetector can be effective between 200 nm and 15 μm for the wavelength λ of the radiation R, and more particularly between 1 μm and 5 μm, especially between 1 μm and 2.5 μm, depending on the photoconductive material used;
the photodetection current can be between 1 μA·W⁻¹ (microampere per watt) and 1 kA·W⁻¹ (kiloampere per watt), more particularly between 1 mA·W⁻¹ (milliampere per watt) and 5 A·W⁻¹ (microampere per watt), and preferentially between 100 mA·W⁻¹ and 2 A·W⁻¹, expressed per unit of radiation power R;
the photodetector response time can be less than 40 ms (millisecond), more particularly less than 1 ms, and preferentially less than 10 μs (microsecond);
the specific detectivity of the photodetector can be greater than 10⁸ cm·Hz^{1/2}·W⁻¹ (centimeter times hertz to the power of one-half per watt: unit also called jones), more particularly greater than 10⁹ cm·Hz^{1/2}·W⁻¹, and preferentially greater than 10¹⁰ cm·Hz^{1/2}·W⁻¹; and
the operating temperature of the photodetector can be higher than 80 K (kelvin), preferentially higher than 150 K, and even more preferentially higher than 200 K.

The photodetection efficiency of a photodetector according to the invention, when the incident radiation R has the wavelength value λ of the coupling resonance λ_{c}, is provided by the two Fabry-Perot resonators FP1 and FP2 that are coupled to each other. For this wavelength value, the photodetector concentrates the radiation in the portion of the photoconductive material of whichever of the two resonators has the greater width, W₁ or W₂. For the photodetector in FIG. 1b, the radiation is more precisely concentrated at the top of the portion of photoconductive material furthest from the substrate 1, inside the resonator FP1. For the photodetector in FIG. 1c, the radiation is concentrated both at the top of the portion of photoconductive material in the resonator FP1, and also in the lower corners of this portion. Generally speaking, the energy density of the radiation is multiplied by a factor of more than 10, or even more than 15, at those points of the photoconductive material portion of the widest resonator, with respect to the energy density of the radiation on its optical path before reaching the photodetector. Owing to this concentration of radiation, a much higher number of electrical charges is generated in the photoconductive material, resulting in increased photodetection efficiency and sensitivity.

In a photodetector according to FIG. 1c, the surface S of the substrate 1 is electrically conductive and in contact with the portions of the photoconductive material 4 that are contained in the resonators FP1 and FP2, while being electrically insulated from the electrodes 31 and 32. The photodetection current can then be collected by any two of the electrode 31, the electrode 32 and the conductive layer 11 acting as an additional electrode. A reconfiguration circuit can be used to select the two electrodes that are actually used to collect the photodetection current when the photodetector is in use. Such a reconfiguration circuit can connect that of the electrode 3₁, the electrode 3₂ and the conductive layer 11 that is not used to collect the photodetection current to one of the other two, or leave it at a floating potential.

The photodetector can be further complemented by a biasing electrical circuit, which is arranged to apply an adjustable electrical voltage between the two electrodes used to collect the photodetection current. The use of such a biasing circuit is well known to those skilled in the art, so it is not necessary to describe it in greater detail here. Generally speaking, for the same pair of electrodes used, the efficiency of collecting the electric charges generated by the radiation R in the layer of photoconductive material 4 increases with the absolute value of the biasing voltage. A further advantage of a photodetector according to the invention lies in the fact that the biasing voltage values to be applied between the electrodes used can be less than 10 V, or even less than 1 V. Such voltage values can therefore be transmitted by an integrated electronic circuit that is implemented using one of the existing technologies. The electric field thus created by the biasing electrical circuit in the photoconductive material can be between 0 and 100 kV·cm⁻¹ (kilovolt per centimeter), and more particularly less than 20 kV·cm⁻¹.

The diagram in FIG. 3b shows the spectral detection response of a photodetector 101 in accordance with FIG. 1b and FIG. 2. The horizontal axis of this diagram marks the wavenumber values, equal to the inverse of the wavelength λ, noted σ and expressed in cm⁻¹, and its vertical axis marks the values of the photodetection current, noted Iₚₕ and expressed in arbitrary units (a.u.), which are obtained when radiation R has a constant intensity and a direction of propagation parallel to direction D₁. The two electrodes used to collect this photodetection current are the electrodes 3₁ and 3₂ as shown in FIG. 2, and the conductive layer 11 is left at a floating potential. A variable biasing voltage is further applied between the two electrodes 3₁ and 3₂, whose values are indicated with reference to each curve in the diagram, from 10 mV (millivolt) to 1000 mV. When this biasing voltage is zero or low, the photodetector has a detection efficiency that results from the coupling resonance as described above, with a detection maximum for a value of around 6500 cm⁻¹ of the wavenumber σ. This detection maximum corresponds to the concentration of radiation in the widest Fabry-Perot resonators, that is, the resonators FP1 in FIG. 1b and FIG. 2. When the biasing voltage is increased, an additional detection contribution appears, the maximum of which is located around 5800 cm⁻¹. This additional contribution, which varies at 5800 cm⁻¹ from 0.12 to 1.0 in the system of axes of the diagram in FIG. 3b, between values of 10 mV and 1000 mV for the biasing voltage, corresponds to a more efficient collection of charges in the portions of photoconductive material 4 that are located in the narrowest Fabry-Perot resonators, that is, the resonators FP2 of FIG. 1b and FIG. 2. Its spectral position, around 5800 cm⁻¹, corresponds substantially to the individual resonance of the Fabry-Perot resonators FP2, which produces a concentration of radiation therein.

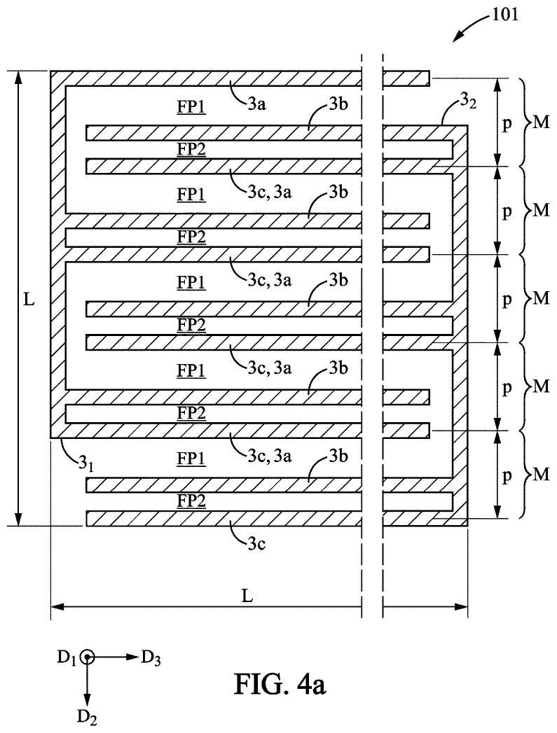

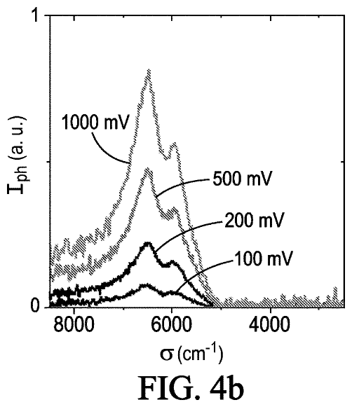

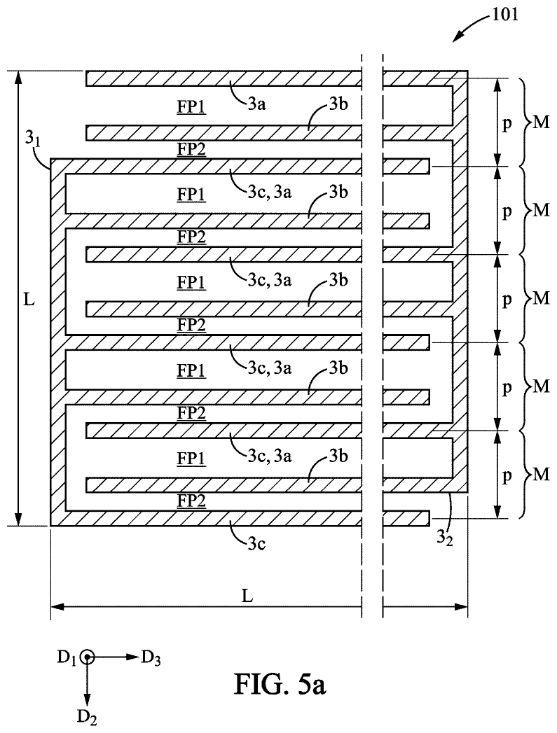

In the photodetector 101 of FIG. 4a, the electrode portions that are intermediate between the Fabry-Perot resonators FP1 and FP2 are connected to the electrodes 3₁ and 3₂ so that for each resonator FP2, the two electrode portions 3b and 3c that are contiguous with this resonator are short-circuited relative to each other, and connected to either electrode 3₁ or electrode 3₂, alternately between two successive resonators FP2. The coupled resonators still have the constitution shown in FIG. 1b, with the width W₂ of the resonators FP2 being smaller than that W₁ of the resonators FP1. The photodetection current is again collected between the two electrodes 3₁ and 3₂, and the variable biasing voltage is applied therebetween. Under these conditions of collection of the photodetection current, its spectral variations become those shown in the diagram in FIG. 4b. Owing to the configuration of the electrodes, the charges generated by the radiation R in the (widest) resonators FP1 are collected efficiently, corresponding to the detection peak at around 6500 cm⁻¹. The detection peak at around 6000 cm⁻¹ corresponds to the photoconductive material 4 outside the resonators FP1. Both peaks are strongly exacerbated by the biasing voltage.

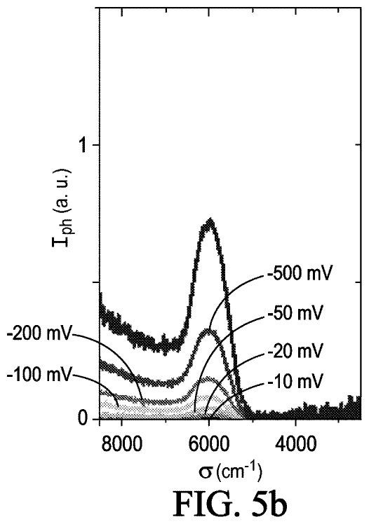

Conversely, in the photodetector 101 of FIG. 5A, which also has the constitution of the pattern M shown in FIG. 1b, it is the electrode portions 3a and 3b contiguous with each resonator FP1 that are short-circuited relative to each other, and connected to one of the two electrodes 3₁ and 3₂ alternately between two successive resonators FP1. Like before, the resonators FP1 have a width W₁ that is greater than the width W₂ of the resonators FP2. The photodetection current is still collected between the two electrodes 3₁ and 3₂, and the variable electrical biasing voltage is likewise applied therebetween. Under these new collection conditions of the photodetection current, its spectral variations are those shown in the diagram of FIG. 5b. Due to the configuration of the electrodes, only the charges generated by the radiation R in the (narrowest) resonators FP2 are collected. The detection peak is then mainly located around 6000 cm⁻¹ and strongly exacerbated by the biasing voltage.

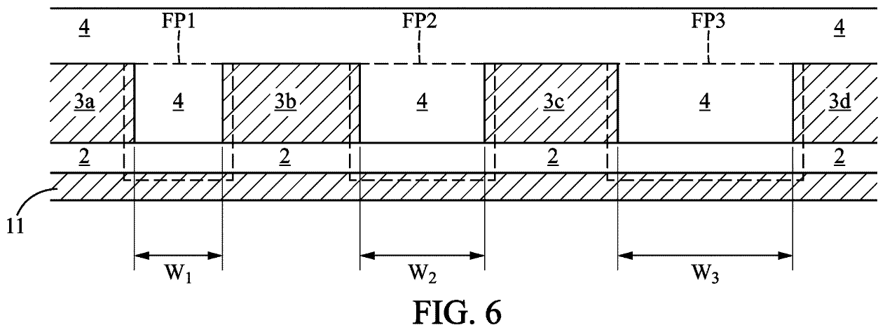

FIG. 6 is a cross-sectional view of yet another photodetector according to the invention. One pattern of this other photodetector consists of more than two, for example three, Fabry-Perot resonators that are juxtaposed with resonator widths that are different in pairs. These three Fabry-Perot resonators are designated FP1, FP2 and FP3, with their respective resonator widths W₁, W₂ and W₃. For example, the width W₃ is greater than the width W₂, which in turn is greater than the width W₁. The electrode portions are designated 3a, 3b, 3c and 3d, and the other references have the same meanings as above. The width of the electrode portion 3b is sufficiently small for the Fabry-Perot resonators FP1 and FP2 to be coupled in accordance with the invention on the one hand, and the width of the electrode portion 3c is likewise sufficiently small for the Fabry-Perot resonators FP2 and FP3 to be coupled on the other hand. Thus, a first photodetection current that can be collected between the electrode portions 3a and 3b has a sensitivity spectrum, based on the wavelength of the radiation to be detected, that results from the coupling between the Fabry-Perot resonators FP1 and FP2, and a second photodetection current that can be collected between the electrode portions 3c and 3d has another sensitivity spectrum that results from the coupling between the Fabry-Perot resonators FP2 and FP3. A third photodetection current, additional to the previous two, can further be collected between the electrode portions 3b and 3c, whose sensitivity spectrum results from the couplings of the Fabry-Perot resonator FP2 with each of the other two, that is, with the two Fabry-Perot resonators FP1 and FP3. It may then be advantageous to adjust an electrical biasing voltage that is applied between the two electrode portions 3b and 3c to adjust the sensitivity spectrum of the third photodetection current. The first, second and third photodetection currents are collected simultaneously, so that they provide three distinct pieces of information on the spectral composition of the detected radiation.

In fact, as can be seen from the above description, the multiplicity of electrical connection modes for the electrode portions, the different possibilities for selecting the electrode pairs to be used to collect the photodetection current, and the biasing voltage simultaneously enable the photodetector to be reconfigured to modify its spectral sensitivity characteristic. The photodetector can therefore be adapted based on its application, or provide measurements of the same radiation in several detection modes.

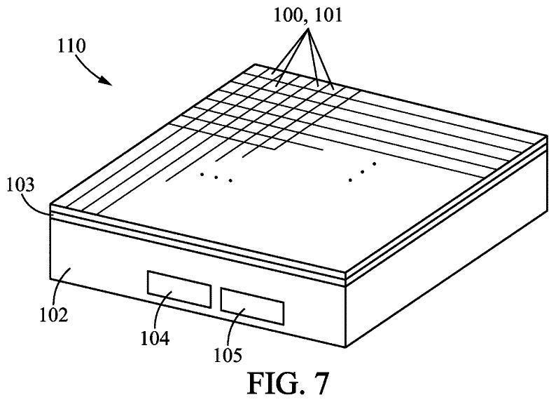

FIG. 7 shows an image sensor according to the invention. This image sensor, which is designated globally by reference 110, comprises a matrix-array of photodetectors 100 or 101 all of the same model, for example one of the models described above. In particular, this photodetector matrix-array can be between 4×4 and 16384×12288 photodetectors, more particularly between 320×200 and 16384×12288 photodetectors. The pitch of the photodetectors in this matrix-array can be between 1 μm and 1 cm, preferably less than 100 μm. When the photoconductive material is deposited using a spin-coating deposition method, the photodetectors can be formed directly on a readout circuit of the image sensor 110. For example, this readout circuit can be manufactured using CMOS technology. This readout circuit, which is designated by reference 102 in FIG. 7, then forms the base substrate 10 of all the photodetectors 100/101. In this case, a set 103 of electrical connection layers can be interposed between the photodetectors 100/101 and the readout circuit 102. These electrical connections link the electrode portions of each photodetector to a readout cell dedicated to that photodetector and contained in the readout circuit 102. Additionally, the readout circuit 102 can advantageously incorporate the reconfiguration circuit and the electrical biasing circuit as introduced above. They are designated in FIG. 7 by reference 104 for the reconfiguration circuit, and by reference 105 for the electrical biasing circuit.

A method of manufacturing a photodetector in accordance with the invention is now described in detail, by way of example. First, a method for obtaining a colloidal solution precursor is provided, along with three examples of photoconductive nanocrystal colloidal solution.

### Molar Solution of Top: Te Precursor (1 M)

A quantity of 6.35 g (gram) of tellurium (Te) powder was mixed with 50 mL (milliliter) of TOP, for tri-octylphosphine, in a first tricol flask. This flask was kept under vacuum at room temperature for 5 minutes, then the temperature was raised to 100° C. Degassing was carried out for a further 20 minutes at this temperature. The atmosphere was replaced by nitrogen (N₂) and the temperature was adjusted to 275° C. The solution was stirred until a clear orange color was obtained. The flask was then cooled to room temperature and the color turned yellow. Finally, this solution was transferred to a nitrogen-filled glovebox for storage.

### Example 1: Synthesis of HgTe Nanocrystals with Band Gap at 6000 cm⁻¹

In a 100 mL tricol flask, 540 mg (milligram) of mercury chloride (HgCl₂) and 50 mL of oleylamine were degassed under vacuum at 110° C. At this stage, the solution is yellow and clear. Meanwhile, 2 mL of TOP:Te precursor molar solution (1 M) was extracted from the glovebox and mixed with 8 mL oleylamine. The atmosphere is replaced by nitrogen and the temperature is set at 57° C. The TOP:Te solution is rapidly injected into the tricol flask and turns dark after 1 minute. After 3 minutes, 10 mL of a solution of DDT, for dodecanethiol, in toluene (10% DDT by volume), is further injected into the tricol flask, and a cold water bath is used to rapidly lower the temperature. The contents of the second tricol flask were divided into four tubes and methanol was added thereto. After centrifugation, the precipitates formed were redispersed in a single tube with 10 mL toluene. The solution was precipitated a second time with ethanol. Again, the precipitate formed was redispersed in 8 mL toluene. In this step, the nanocrystals were centrifuged in pure toluene to remove the lamellar phase. The solid phase was removed and the supernatant filtered using a 0.2 μm polytetrafluoroethylene, or PTFE, filter.

### Example 2: Synthesis of HgTe Nanocrystals with Band Gap at 4000 cm⁻¹

In a 100 mL tricol flask, 540 mg of mercuric chloride (HgCl₂) and 50 ml of oleylamine were degassed under vacuum at 110° C. At this stage, the solution is yellow and clear. Meanwhile, 2 mL of TOP:Te of the precursor molar solution (1 M) was extracted from the glovebox and mixed with 8 mL oleylamine. The atmosphere is replaced by nitrogen and the temperature is set at 86° C. The TOP:Te solution is rapidly injected into the tricol flask and turns dark after 1 minute. After 3 minutes, 10 mL of a solution of DDT, for dodecanethiol, in toluene (10% DDT by volume), is further injected into the tricol flask, and a cold water bath is used to rapidly lower the temperature. The contents of the tricol flask were divided into four tubes and methanol was added thereto. After centrifugation, the precipitates formed were redispersed in a single tube with 10 mL toluene. The solution was precipitated a second time with ethanol. Again, the precipitate formed was redispersed in 8 mL toluene. In this step, the nanocrystals were centrifuged in pure toluene to remove the lamellar phase. The solid phase was removed and the supernatant filtered using a 0.2 μm polytetrafluoroethylene, or PTFE, filter.

### Example 3: Synthesis of Pbs Nanocrystals With Band Gap at 6000 cm¹

In a tricol flask, 300 mg lead chloride (PbCh) and 7.5 mL oleylamine are degassed at room temperature and then at 110° C. for 30 minutes. Meanwhile, 30 mg sulfur powder(S) is mixed with 7.5 mL oleylamine until completely dissolved, by stirring in the presence of ultrasound, to obtain a clear orange solution. Then, under a nitrogen atmosphere at 160° C., this sulfur solution is rapidly added to the tricol flask. After 15 minutes, the reaction is quickly stopped by adding 1 mL oleic acid and 9 mL hexane. The nanocrystals are precipitated with ethanol, centrifuged and redispersed in toluene. This washing step is repeated an additional time. The nanocrystal solution in toluene is then centrifuged to remove the unstable phase. The supernatant is precipitated with methanol and then redispersed in toluene. Finally, the solution of PbS nanocrystals in toluene is filtered using a 0.2 μm polytetrafluoroethylene, or PTFE, filter.

The manufacture of the coupled Fabry-Perot resonator photodetector in accordance with the invention is described now and comprises the following steps 1 to 5:

### Step 1: Mirror Formation to Form the Reflective Layer

Silica-coated silicon substrates, 12 mm×14 mm in size, are cleaned with acetone and isopropanol. They are placed in an acetone bath and subjected to ultrasound for 5 minutes. They are then rinsed with acetone and isopropanol, and dried under nitrogen flow. These substrates are then cleaned with an oxygen (O₂) plasma for 5 minutes. An adhesion promoter, e.g. TI Prime® supplied by MicroChemicals®, is deposited by spin-coating, e.g. at 4000 revolutions per minute (rpm) for 30 seconds, and baked at 120° C. for 2 minutes. Resin, for example AZ 5214, is then deposited by spin-coating, for example at 4000 rpm for 30 seconds, then annealed at 110° C. for 90 seconds. The substrates are then exposed to ultraviolet (UV) radiation through a mask for 1.5 seconds, then annealed at 125° C. for 2 minutes. A second ultraviolet radiation exposure is then performed, for example for 40 seconds, without a mask. The resin is developed in a developer, such as the AZ 726 MIF model, for 30 seconds and then rinsed with deionized water for 15 seconds. Each substrate is then cleaned with oxygen plasma for 5 minutes. A first layer of titanium (Ti), 3 nm thick, followed by a second layer of gold (Au), 80 nm thick, are deposited using a thermal evaporator, preferably with sample rotation. Finally, a third layer of aluminum (Al), 5 nm thick, is deposited, again using a thermal evaporator. The resin is then removed by soaking each sample in acetone for 1 hour. The substrates are then rinsed with acetone and isopropanol and dried under nitrogen flow. The mirror thus obtained on each silicon-based substrate is intended to form the reflective layer 11 mentioned in connection with FIG. 1a-FIG. 1d.

### Step 2: Depositing the Insulating Layer

A 50 nm-thick layer of alumina (Al₂O₃) is deposited on each substrate using the ALD (atomic layer deposition) method. This layer is intended to form the insulating layer 2 mentioned in connection with FIG. 1a-FIG. 1d.

### Step 3: Formation of Macroscopic Electrical Contact Zones

The substrates are rinsed with acetone and isopropanol and dried under nitrogen flow. An adhesion promoter, e.g. TI Prime® supplied by MicroChemicals®, is deposited by spin-coating, e.g. at 4000 rpm for 30 seconds, then baked at 120° C. for 2 minutes. AZ 5214 resin is then deposited by spin-coating, for example at 4000 rpm for 30 seconds, then annealed at 110° C. for 90 seconds. Each substrate is then exposed to ultraviolet radiation through a mask for 1.5 seconds, then annealed at 125° C. for 2 minutes. A second exposure to ultraviolet radiation is then performed for 40 seconds, without a mask. The resin is developed in the AZ 726 MIF developer for 30 seconds, then rinsed with deionized water for 15 seconds. Each substrate is then cleaned with oxygen plasma for 5 minutes. A layer of titanium 3 nm thick, then another layer of gold 150 nm thick, are deposited by thermal evaporation, preferably with substrate rotation. The resin is then removed by soaking the sample in acetone for 1 hour. The substrates are then rinsed with acetone and isopropanol, and dried under nitrogen flow.

### Step 4: Electron-Beam Lithography

The substrates are rinsed with isopropanol, then dried under nitrogen flow. A layer of pure grade A6 polymethylmethacrylate, or PMMA, is deposited by spin-coating at 400 rpm for 5 seconds, then at 4000 rpm for 30 seconds, and baked at 180° C. for 2 minutes. A 10 nm layer of aluminum is then deposited using an electron-beam evaporator. The aluminum deposition rate is set at 0.1 nm·s¹ (nanometer per second) and sample rotation is activated in the evaporator.

Each substrate is then transferred to an electron lithography device. Electron lithography is performed with a current of 12 pA (picoampere) and a total dose of 200 μC·cm⁻² (microcoulomb per square centimeter). The substrate is then immersed for 15 seconds in a solution of potassium hydroxide, or KOH, at 40 g in 100 ml of water, rinsed with water and dried under a stream of nitrogen. This eliminates the aluminum layer. The PMMA resin is developed using a 1:3 solution by volume of methyl isobutyl ketone, or MIBK: isopropanol, or IPA, for 45 seconds, then rinsed in pure isopropanol for 20 seconds. Each substrate is then cleaned with oxygen plasma for 2 minutes. It is then transferred to the electronic evaporator. A 3 nm-thick layer of titanium is deposited, followed by an 80 nm-thick layer of gold, at deposition rates of 0.1 nm·s⁻¹ and 0.2 nm·s⁻¹, respectively. The resin is then removed by immersing each substrate in acetone at 40° C. for at least 2 hours. The metal portions thus formed on each substrate are the electrodes 3₁ and 3₂ mentioned in connection with FIG. 2, FIG. 4a and FIG. 5a. The substrates are then observed under a scanning electron microscope, with the parameters 8 mm and 5 kV, and the electrodes are electrically controlled.

### Step 5: Nanocrystal Deposition

A 1 mL solution of HgTe nanocrystals with a bandgap of 6000 cm⁻¹, that is, 720 meV (millielectron volt), in toluene and an optical density of 0.9 at 400 nm, is mixed with 1 mL of a ligand exchange solution, the latter consisting of the following proportions: 9 mL dimethylformamide, 1 mL mercapthoethanol and 15 mg HgCl₂. Three successive cleaning steps are performed using hexane. The nanocrystals are then precipitated with toluene. After centrifugation, the supernatant is removed and the pellet is dried under vacuum for 15 minutes. The pellet is redispersed in 170 μL (microliter) of pure dimethylformamide. This ink is then deposited by spin-coating on each substrate at 2000 rpm (acceleration 200 rpm/s, rotation time 120 s). Beforehand, the substrate has been exposed to oxygen plasma for 4 minutes.

It is understood that the invention can be reproduced by modifying secondary aspects of the embodiments that have been described in detail above, while retaining at least some of the cited advantages. In particular, all the numerical values provided are for illustrative purposes only and may be changed depending on the application in question.

1-16. (canceled)

17. A photodetector comprising:
a substrate, which is reflective to electromagnetic radiation incident on the photodetector;
electrode portions, which are supported by the substrate, and which have respective surfaces facing away from the substrate, referred to as upper surfaces and located at a common level of spacing from said substrate;
portions of an electrically insulating material, which are located between the electrode portions and the substrate, so as to electrically insulate each electrode portion from the substrate; and
at least one portion of a photoconductive material, which is arranged to be in electrical contact with two of the electrode portions which are adjacent, at least two of the electrode portions and the substrate being intended to collect a photodetection current when the photodetector is in use, characterized in that a first and a second of the electrode portions which are adjacent delimit therebetween, parallel to the substrate, a volume into which, when the photodetector is in use, the radiation penetrates in order to be reflected by the substrate, forming a first Fabry-Perot resonator between said substrate and the level of the upper surfaces of the electrode portions,
and in that the second electrode portion and a third of the electrode portions, which is located on a side of said second electrode portion opposite said first electrode portion, delimit therebetween, parallel to the substrate, another volume into which, when the photodetector is in use, the radiation also penetrates to be reflected by the substrate, forming a second Fabry-Perot resonator between said substrate and the level of the upper surfaces of the electrode portions,
the first and second Fabry-Perot resonators being designed to generate standing-wave components that propagate perpendicular to the substrate when the photodetector is in use, and in that the photodetector has the following features /1/ to /3/:
/1/ a width of the first Fabry-Perot resonator, measured between the first and second electrode portions parallel to the substrate, is different from a width of the second Fabry-Perot resonator, measured between the second and third electrode portions also parallel to the substrate, so that the first and second Fabry-Perot resonators have respective individual resonance wavelength values, effective for the radiation incident on the photodetector, which are different, with respective values of an individual resonance quality factor of the first and second Fabry-Perot resonators such that, on one wavelength axis of the incident radiation, the following individual resonance intervals: [λᵣᵢ·(1−3/Qᵢ); λᵣᵢ(1+3/Qᵢ)], have an overlap, where i is equal to 1 or 2 to designate the first or second Fabry-Perot resonator, respectively, and λᵣᵢ and Qᵢ are respectively the wavelength and quality factor values of the individual resonance of the Fabry-Perot resonator i;
/2/ a sum of the widths of the first and second Fabry-Perot resonators with the width of the second electrode portion, measured parallel to the substrate between the volumes of the first and second Fabry-Perot resonators, is adapted to produce a coupling between said first and second Fabry-Perot resonators, by being less than a resonance wavelength value relative to the coupling, known as the coupling resonance wavelength, which is effective for the radiation incident on the photodetector, and which results from interference between at least three waves, including:
a first wave resulting from the reflection of incident radiation on the substrate;
a second wave emerging from the first Fabry-Perot resonator, resulting from a superposition of several wave components, among which at least one of said wave components has made at least one round trip within the volume of the second Fabry-Perot resonator; and
a third wave emerging from the second Fabry-Perot resonator, resulting from another superposition of several other wave components, among which at least one of said other wave components has made at least one round trip within the volume of the first Fabry-Perot resonator; and
/3/ the photoconductive material is absorbent for the coupling resonance wavelength, and the portion of said photoconductive material is located in or on at least one of the volumes of the first and second Fabry-Perot resonators.

18. The photodetector according to claim 17, wherein the substrate comprises a photodetector readout circuit.

19. The photodetector according to claim 17, wherein the portions of electrically insulating material are parts of a continuous layer of said insulating material which extends across the volumes of the first and second Fabry-Perot resonators, in addition to extending between the substrate and each electrode portion.

20. The photodetector according to claim 17, wherein the substrate is also in contact with the portion of photoconductive material, in addition to the first, second and third electrode portions, so as to form an additional electrode portion.

21. The photodetector according to claim 17, further comprising a biasing electrical circuit which is adapted to apply, during use of the photodetector, an electrical voltage between two of the electrode portions which collect the photodetection current, said biasing electrical circuit being further adapted to vary said electrical voltage between two successive uses of the photodetector, so as to modify a sensitivity spectrum, in particular a detection sensitivity, of said photodetector.

22. The photodetector according to claim 21, adapted so that a radiation absorption value at least at one wavelength value varies by at least 30%, preferably at least 50%, even more preferably at least 90%, between a first use of the photodetector with no electrical voltage applied by the biasing electrical circuit between the two electrode portions, or during which said applied electrical voltage is zero, and a second use of said photodetector during which said applied electrical voltage is non-zero.

23. The photodetector according to claim 17, further comprising a reconfiguration circuit which is adapted to select and electrically connect at least two of the electrode portions and substrate of the photodetector in order to collect photodetection current by those electrode and substrate portions which are selected, those electrode and substrate portions which are selected varying between several modes of photodetection current collection, which are associated with different respective spectra of photodetector sensitivity to incident radiation.

24. The photodetector according to claim 17, wherein each portion of the photoconductive material is part of a layer of said photoconductive material which extends continuously over the volumes of the first and second Fabry-Perot resonators and over the electrode portions.

25. The photodetector according to claim 17, comprising a plurality of pairs of coupled first and second Fabry-Perot resonators, with first, second and third electrode portions associated with each pair and electrically connected to accumulate photodetection currents which arise from each pair when the photodetector is in use.

26. The photodetector according to claim 17, having lateral dimensions which are between 1 μm and 1 cm, preferably between 1 μm and 100 μm, measured parallel to the substrate.

27. The photodetector according to claim 17, wherein the volumes of the first and second Fabry-Perot resonators, as well as the width of the second electrode portion, are dimensioned so that the coupling resonance wavelength is between 1 μm and 12 μm.

28. The photodetector according to claim 17, wherein the photoconductive material is selected to have a bandgap which is less than 0.8 eV.

29. The photodetector according to claim 17, wherein each portion of photoconductive material consists of agglomerated nanocrystals.

30. An image sensor, comprising a matrix arrangement of photodetectors, each photodetector being in accordance with claim 17.

31. The image sensor according to claim 30, wherein each photodetector has an individual photodetector size, measured along a direction of juxtaposition of the pairs of coupled first and second Fabry-Perot resonators, which is less than or equal to ten times a wavelength value of the radiation corresponding to a maximum detection sensitivity of the photodetector.

32. A method of manufacturing a photodetector, said photodetector being in accordance with claim 17, according to which the portions of photoconductive material are obtained from a deposition of a colloidal solution which incorporates nanocrystals of the photoconductive material, followed by drying of the deposited colloidal solution.
